(19) United States
(12) Patent Application Publication
(10) Pub. No.: US 2007/0241463 A1
(43) Pub. Date: Oct. 18, 2007

(54) ELECTRODE, MANUFACTURING METHOD OF THE SAME, AND SEMICONDUCTOR DEVICE HAVING THE SAME

(75) Inventors: Masahiro Yamaguchi, Tokyo (JP); Hirofumi Nakamura, Tokyo (JP)

Correspondence Address: SUGHRUE MION, PLLC, 2100 PENNSYLVANIA AVENUE, N.W., SUITE 800, WASHINGTON, DC, 20037, US

(73) Assignees: ELPIDA MEMORY, INC., Tokyo (JP); NEC TOPPAN CIRCUIT SOLUTIONS, INC., Tokyo (JP)

(21) Appl. No.: 11/735,836

(22) Filed: Apr. 16, 2007

(30) Foreign Application Priority Data
Apr. 17, 2006 (JP) 2006-113195

(51) Int. Cl. H01L 23/52; H01L 23/48; H01L 29/40

(52) U.S. Cl. 257/777

(57) ABSTRACT

Metal posts are formed by etching a metal plate. Therefore, the metal posts can be formed with an accurate height and at a fine pitch. By connecting together upper and lower packages using the metal posts formed in the upper package, there is obtained a miniaturized semiconductor device having a fine electrode pitch.

This application claims priority to prior Japanese patent application JP2006-113195, the disclosure of which is incorporated herein by reference.

### BACKGROUND OF THE INVENTION

This invention relates to electrodes of a semiconductor device and, in particular, relates to electrodes for a PoP (Package-on-Package) structure in which packages mounted with semiconductor elements are stacked together, a manufacturing method of such electrodes, and a semiconductor device having such electrodes.

In recent years, semiconductor devices have increased in speed and capacity and, further, semiconductor device packages have been miniaturized for miniaturization of electronic systems. Particularly, the miniaturization of packages is important in portable devices and there have been employed those semiconductor devices each having a plurality of semiconductor chips mounted in a package. As these semiconductor devices, proposals have been made about a MCP (Multi-Chip Package) having a plurality of semiconductor chips stacked in the package and a PoP device in which a plurality of CSPs (Chip Size Packages) are stacked together. Further, a flip-chip bonding method using bonding pads formed as bumps, or the like has been employed as a semiconductor chip connection method other than a conventional wire bonding method. This makes it possible to achieve miniaturization of semiconductor devices.

FIG. 3 is a sectional view of a semiconductor device having a conventional PoP structure. In the illustrated semiconductor device, an upper package has resin-sealed semiconductor chips 9-1 and 9-2 and is connected to a lower package at their lands 3 through solder balls 16-2. Specifically, the lower package is mounted with a semiconductor chip 9-3 and has the connection lands 3 on the top side thereof and solder balls 16-1 provided on the bottom side thereof. The semiconductor chips 9-1 and 9-2 are mounted on the top side of the upper package and connected to electrodes of an upper package board by wire bonding. The lands 3 for connection to the lower package are formed on the bottom side of the upper package.

In this PoP structure, in order to connect the upper and lower packages together, it is necessary to ensure a space or a gap (standoff) required for the height of the semiconductor chip 9-3 mounted in the lower package. This standoff is maintained by the height of the solder ball. However, since the sphericity of a solder ball is determined by the physical properties of a solder itself, it is impossible to optionally form a vertically elongated shape. Therefore, each of the solder balls 16-2 connecting the upper and lower packages is required to have a diameter greater than the standoff. On the other hand, in terms of an increase in the number of connection terminals (I/O terminals), miniaturization of packages, and so on, it is necessary to reduce the size of connection solder balls and narrow the connection electrode pitch. However, in the case of the solder balls, there is a problem that if the ball diameter is reduced, the standoff amount decreases. Conversely, if the diameter of the solder balls 16-2 for connecting the upper and lower packages is formed greater than that of the solder ball 16-1 for connection to a board, there arises a problem that the package increases in size due to the number of terminals.

In order to cope with this problem, a connection method using other than solder balls is considered. For example, patent document 1 (Japanese Unexamined Patent Application Publication (JP-A) No. 2004-14571) discloses a semiconductor device having metal posts formed on a semiconductor element. In patent document 1, a plating method is used for forming the metal posts. However, there is a problem that the metal posts vary in height by the plating method. On the other hand, in patent document 2 (Japanese Unexamined Patent Application Publication (JP-A) No. 2004-228403), a semiconductor element and a connection pattern of an opposing board are connected together through conductive posts. However, in patent document 2, a problem takes place about positioning of the conductive posts. The techniques of these prior art documents are insufficient for application to a semiconductor device with many terminals in which the connection electrode pitch is narrowed.

In addition, with the advanced functionality, the semiconductor devices increase in the number of connection terminals, so that the narrowing of the connection terminal pitch has been demanded.

However, no electrode connection technique for a PoP structure has been established in order to sufficiently narrow the connection electrode pitch.

### SUMMARY OF THE INVENTION

It is therefore an object of this invention to provide an electrode for a PoP structure that makes it possible to narrow a terminal pitch, a manufacturing method of such an electrode, and a semiconductor device having such an electrode.

For accomplishing the object described above, this invention basically employs techniques which will be described below. It is readily understood that this invention also includes various applied techniques achievable within the range of the gist of such techniques.

An electrode manufacturing method of this invention comprises a step of etching a metal plate from its back side, thereby forming metal posts having a height equal to a thickness of the metal plate.

The electrode manufacturing method of this invention may be featured in that there are provided, before the step of forming the metal posts, a step of forming a wiring board on a surface of the metal plate and a step of mounting a semiconductor chip on the wiring board and resin-sealing it.

The electrode manufacturing method of this invention may be also featured in that the step of forming the wiring board comprises a step of forming a land by coating a plating resist on the surface of the metal plate, patterning the plating resist, and then plating, a step of forming an insulating resin layer for protecting the land, and a step of forming a through hole in the insulating resin layer to thereby form an electrode connected to the land.

The electrode manufacturing method of this invention may be further featured in that the land is formed by plating nickel, gold, nickel, and copper in the order named.

The electrode manufacturing method of this invention may be featured in that the electrode is formed by copper plating.

The electrode manufacturing method of this invention may be featured in that the step of forming the metal post/posts comprises coating an etching resist on the back side of the metal plate, patterning the etching resist to provide a pattern adapted to leave a region of the metal plate corresponding to the land, and then etching the metal plate using the pattern.

The electrode manufacturing method of this invention may be featured in that the metal posts are formed from the metal plate containing copper as a main component.

An electrode of this invention is manufactured by any one of the foregoing electrode manufacturing methods.

A semiconductor device of this invention comprises an electrode manufactured by any one of the foregoing electrode manufacturing methods.

The semiconductor device of this invention may be featured in that a package having the metal posts is used as an upper package and the metal posts and a land of a lower package are connected together by soldering.

Since metal posts of this invention are formed by etching a metal plate, there is obtained an effect that the metal posts can be formed with an accurate height. Further, by connecting together upper and lower packages using metal posts of this invention formed in the upper package, there is an effect that it is possible to obtain a miniaturized PoP structure semiconductor device having a fine electrode pitch and an accurate height.

### BRIEF DESCRIPTION OF THE DRAWINGS

FIG. 1 is a sectional view of a PoP structure semiconductor device according to an embodiment of this invention;

FIGS. 2A to 2P are sectional views showing main processes according to the manufacturing flow for explaining a manufacturing method of the PoP structure semiconductor device according to the embodiment of this invention; and

FIG. 3 is a sectional view of a conventional PoP structure semiconductor device.

### DESCRIPTION OF THE PREFERRED EMBODIMENT

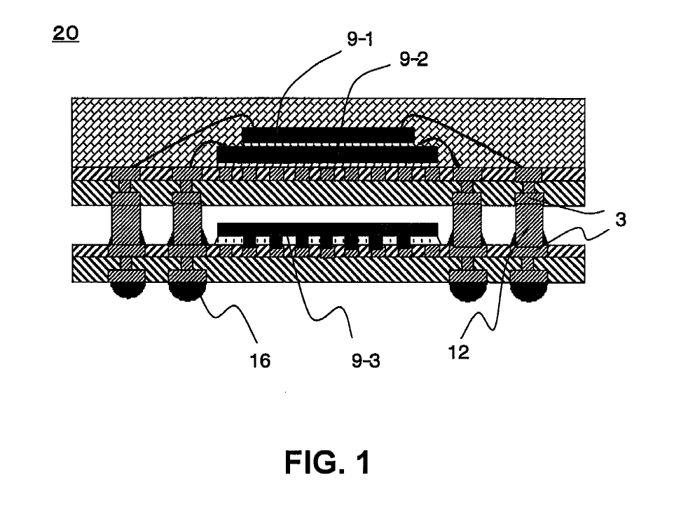

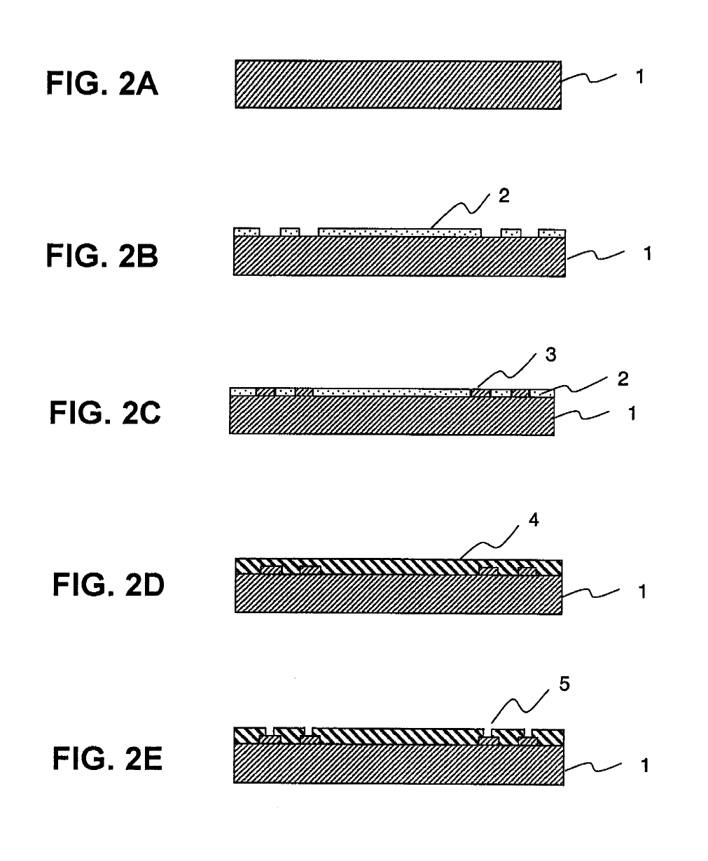

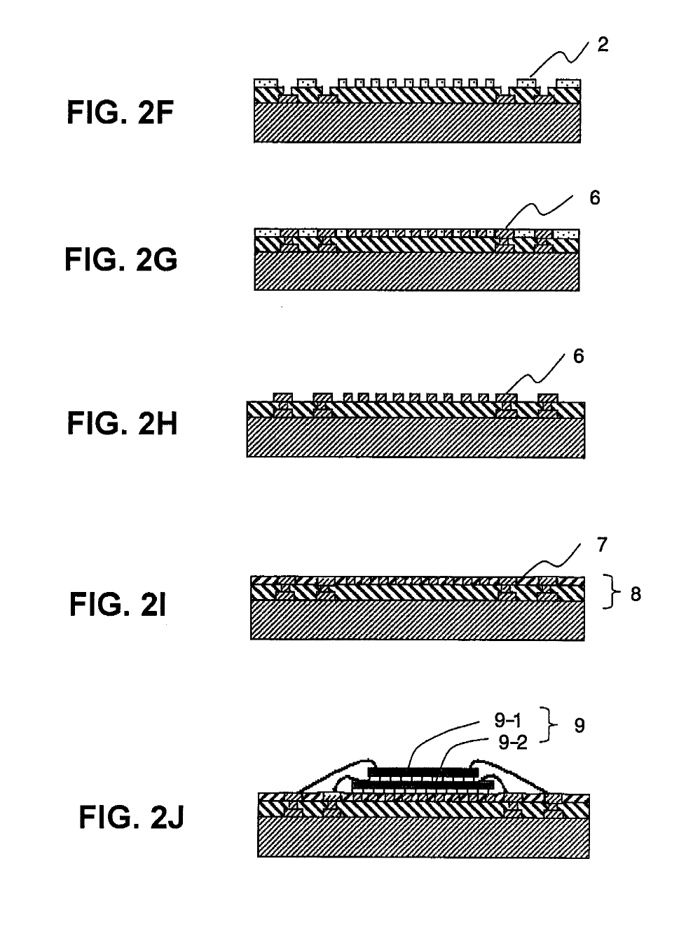

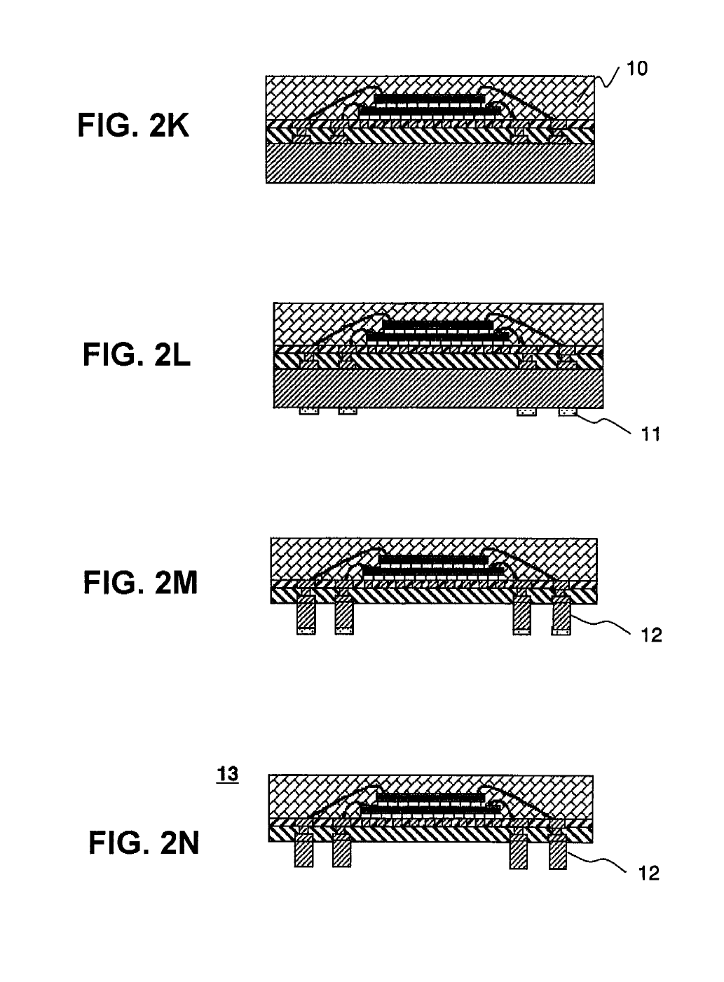

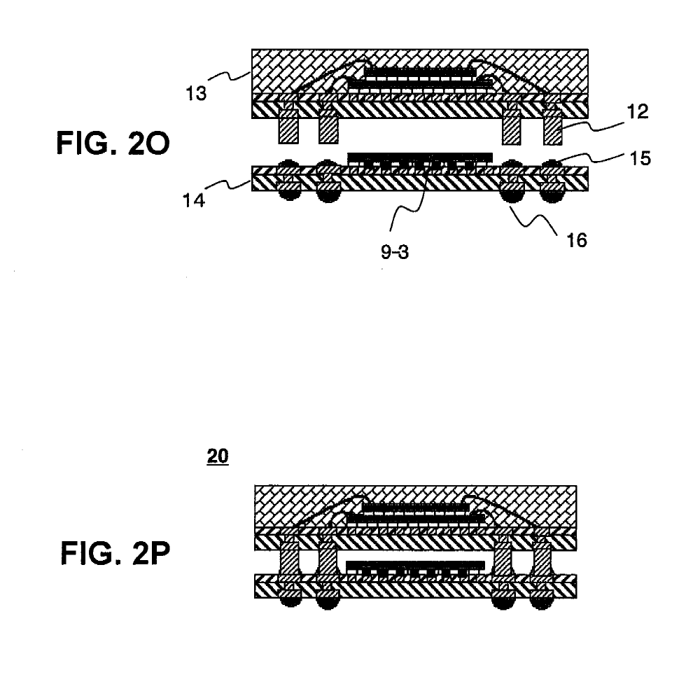

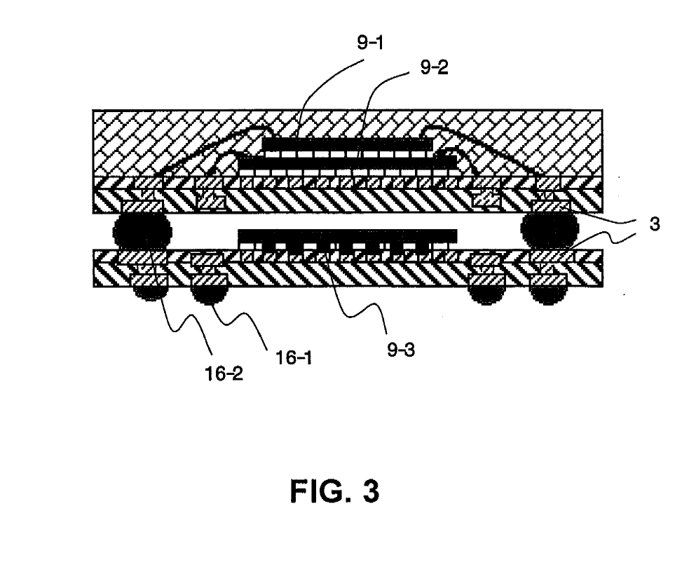

An electrode structure and a manufacturing method thereof according to an embodiment of this invention will be described in detail with reference to FIG. 1 and FIGS. 2A to 2P. FIG. 1 is a sectional view of a PoP structure semiconductor device according to the embodiment of this invention. FIGS. 2A to 2P are sectional views showing main processes according to the manufacturing flow for explaining the manufacturing method of the PoP structure semiconductor device shown in FIG. 1.

At first, the manufacturing method of the electrodes and the PoP structure semiconductor device will be described according to the manufacturing flow with reference to FIGS. 2A to 2P. As shown in FIG. 2A, a copper plate 1 is first prepared as a metal plate for forming metal posts. This metal is not particularly limited as long as it is a metal excellent in conductivity and heat dissipation. For example, it is preferable to use copper excellent in conductivity and heat dissipation or a metal containing copper as a main component. The thickness of the copper plate 1 directly corresponds to the height of copper posts and is set to, for example, 200 μm. Then, lands 3 of an upper package in the PoP structure are formed on an upper surface of the copper plate 1. The lands 3 are formed by patterning a plating resist 2 (FIG. 2B) and carrying out a plating process (FIG. 2C). In this plating process, nickel, gold, nickel, and copper are plated in the order named. After completion of the plating, the plating resist 2 is removed.

Then, an insulating resin layer 4 is formed for protecting the lands 3 (FIG. 2D) and perforation is performed at portions, which will serve as through holes 5, using, for example, a carbon dioxide laser (FIG. 2E). Then, again using a plating resist 2 and carrying out a plating process, the through holes 5 are filled with a plating metal and, further, connection patterns and electrodes 6 are formed (FIGS. 2F and 2G). In this plating process, copper plating is carried out. After removing the plating resist 2 (FIG. 2H), a solder resist 7 is formed (FIG. 2I).

In the case of forming a plurality of connection layers, the processes of insulating resin layer formation, laser perforation, and plating may be repeated necessary times. Through the foregoing processes, there is formed, on the copper plate 1, a wiring board 8 having the connection patterns and the electrodes 6 necessary for mounting semiconductor chips thereon. Then, semiconductor chips 9 are mounted on the wiring board 8. In this embodiment, two semiconductor chips 9-1 and 9-2 are stacked on the wiring board 8 and connected thereto by wire bonding (FIG. 2J). Then, the semiconductor chips 9 and bonding wires are covered with a sealing resin 10 so as to be integrally sealed with the wiring board 8 (FIG. 2K).

Then, an etching resist 11 is subjected to patterning so as to remain at portions on the copper plate 1 where copper posts are to be formed (FIG. 2L) and, by etching the copper plate 1, copper posts 12 are formed (FIG. 2M). Accordingly, the height of each copper post 12 is equal to the thickness of the copper plate 1 and, since the thickness accuracy of the copper plate 1 is excellent, the height of each copper post 12 is also highly accurate. In this etching, since the semiconductor chips 9 and the wiring board 8 mounted with the semiconductor chips 9 are integrally sealed by the sealing resin 10, there is no influence of corrosion by the etching. After the etching of the copper plate 1, the etching resist 11 is removed and then cuffing is performed at predetermined portions, thereby obtaining a package 13 formed with the copper posts 12 (FIG. 2N). The copper posts 12 are connected to the lands 3, thus serving as electrodes of the package 13.

As described above, the copper posts 12 are formed by etching the copper plate and each have the height equal to the thickness of the copper plate. The thickness of the copper plate is hardly subjected to variation and thus is excellent in accuracy. Consequently, the height accuracy of the copper posts is also excellent with no variation. Further, since etching with a resist pattern enables fine patterning, the pitch of the copper posts can be finely narrowed. Accordingly, the copper posts according to this embodiment are optimal as fine-pitch electrodes and thus are optimal for an upper package of a PoP structure semiconductor device having many terminals.

Further, a separately prepared lower package 14 and the upper package 13 are connected together. The lower package 14 is provided with solder balls 16 on the bottom side thereof and with a semiconductor chip 9-3 on the top side thereof and, further, a solder paste 15 is applied to lands 3 formed on the top side thereof (FIG. 2O). The copper posts 12 of the upper package 13 and the solder paste 15 on the lands 3 of the lower package 14 are bonded together by reflow heating. Thus, the upper and lower packages 13 and 14 are integrated together, thereby obtaining a PoP structure semiconductor device 20 (FIG. 2P and FIG. 1). An underfill material or the like may be filled between the upper and lower packages 13 and 14.

In this manner, the PoP structure semiconductor device 20 of FIG. 1 is fabricated by connecting together the upper and lower packages 13 and 14 using the copper posts 12. In the upper package 13, the semiconductor chips 9-1 and 9-2 are mounted and the copper posts 12 are connected to the lands 3. The lower package 14 is mounted therein with the semiconductor chip 9-3 and formed with the lands 3. The copper posts 12 of the upper package and the solder paste on the lands 3 of the lower package are bonded together by the reflow heating, thereby forming the PoP structure semiconductor device 20. The standoff between the upper and lower packages in this PoP structure is determined by the height of each copper post. Since the standoff is determined by the height of each copper post, it is excellent without variation.

According to the embodiment of this invention, the upper and lower packages of the PoP structure semiconductor device are connected together by soldering using the copper posts formed in the upper package. The copper posts are formed, after mounting the semiconductor chips on the wiring board formed on the copper plate and sealing the package, by etching the copper plate from its back side, i.e. the side opposite to the side where the wiring board is formed. Using the thickness of the copper plate as the height of each copper post, it is possible to ensure the height for the standoff while achieving the fine electrode pitch. Since the accuracy of the thickness of the copper plate is excellent, the accuracy of the standoff of the PoP structure semiconductor device is also excellent, as mentioned before. Since the etching makes it possible to process the copper posts to fine dimensions, highly-accurate and small-sized connection electrodes are obtained. Accordingly, there is obtained a highly-accurate and miniaturized PoP structure semiconductor device with many connection terminals using the copper posts as the connection electrodes.

While this invention has been described in detail in terms of the embodiment, the invention is not to be limited thereto, but can be embodied in various ways without departing from the principle of the invention, which are naturally included in this invention.

What is claimed is:

1. An electrode manufacturing method comprising a step of etching a metal plate from its back side, thereby forming metal posts having a height determined by a thickness of said metal plate.

2. An electrode manufacturing method according to claim 1, further comprising, before the step of forming said metal posts, a step of forming a wiring board on a surface of said metal plate and a step of mounting a semiconductor chip on said wiring board and resin-sealing it.

3. An electrode manufacturing method according to claim 2, wherein the step of forming said wiring board comprises a step of forming a land by coating a plating resist on the surface of said metal plate, patterning said plating resist, and then plating, a step of forming an insulating resin layer for protecting said land, and a step of forming a through hole in said insulating resin layer to thereby form an electrode connected to said land.

4. An electrode manufacturing method according to claim 3, wherein said land is formed by plating nickel, gold, nickel, and copper in the order named.

5. An electrode manufacturing method according to claim 3, wherein said electrode is formed by copper plating.

6. An electrode manufacturing method according to claim 1, wherein the step of forming said metal posts comprises coating an etching resist on the back side of said metal plate, patterning said etching resist to provide a pattern adapted to leave a region of said metal plate corresponding to a land, and then etching said metal plate using said pattern.

7. An electrode manufactured by the electrode manufacturing method according to claim 1.

8. An electrode according to claim 7, wherein said metal posts is formed from the metal plate containing copper as a main component.

9. A semiconductor device comprising an electrode manufactured by the electrode manufacturing method according to claim 1.

10. A semiconductor device according to claim 9, wherein a package having said metal posts are used as an upper package and said metal post and a land of a lower package are connected together by soldering.
